(19) United States
(12) Patent Application Publication
(10) Pub. No.: US 2012/0152341 A1
(43) Pub. Date: Jun. 21, 2012

(54) LOW BOW ALUMINUM PASTE WITH AN ALKALINE EARTH METAL SALT ADDITIVE FOR SOLAR CELLS

(75) Inventors: Zhigang Rick LI, Hockessin, DE (US); Liang Liang, Hockessin, DE (US); Raj G. Rajendran, Hockessin, DE (US)

(73) Assignee: E.I. DU PONT DE NEMOURS AND COMPANY, Wilmington, DE (US)

(21) Appl. No.: 12/969,908

(22) Filed: Dec. 16, 2010

(51) Int. Cl. H01L 31/0224; H01B 1/22; H01L 31/18

(52) U.S. Cl. 136/256; 438/98; 252/501.1; 257/E31.124

(57) ABSTRACT

The present invention relates to a composition for use as a backside conductive paste in solar cells. The paste comprises aluminum powder, an organic vehicle and an additive comprising a salt of an alkaline earth metal ion and an organic counterion.

### FIELD OF THE INVENTION

The present invention relates to a composition for use as a backside conductive paste in solar cells. The paste comprises aluminum powder, an organic vehicle and an additive comprising a salt of an alkaline earth metal ion and an organic counterion.

### TECHNICAL BACKGROUND OF THE INVENTION

A conventional solar cell structure with a p-type base has a negative electrode that is typically on the front-side or sun side of the cell and a positive electrode on the back-side. It is well known that radiation of an appropriate wavelength falling on a p-n junction of a semiconductor body serves as a source of external energy to generate hole-electron pairs in that body. The potential difference that exists at a p-n junction, causes holes and electrons to move across the junction in opposite directions and thereby give rise to flow of an electric current that is capable of delivering power to an external circuit. Most solar cells are in the form of a silicon wafer that has been metalized, i.e., provided with metal contacts which are electrically conductive.

During the formation of a silicon solar cell, an aluminum paste is generally screen printed and dried on the back-side of the silicon wafer. The wafer is then fired at a temperature above the melting point of aluminum to form an aluminum-silicon melt, subsequently, during the cooling phase, a epitaxially grown layer of silicon is formed that is doped with aluminum. This layer is generally called the back surface field (BSF) layer, and helps to improve the energy conversion efficiency of the solar cell.

Most electric power-generating solar cells currently used are silicon solar cells. Process flow in mass production is generally aimed at achieving maximum simplification and minimizing manufacturing costs. Electrodes in particular are made by using a method such as screen printing from a metal paste.

An example of this method of production is described below in conjunction with FIG. 1. FIG. 1A shows a p-type silicon substrate, 10.

In FIG. 1B, an n-type diffusion layer, 20, of the reverse conductivity type is formed by the thermal diffusion of phosphorus (P) or the like. Phosphorus oxychloride (POCl₃) is commonly used as the gaseous phosphorus diffusion source, other liquid sources are phosphoric acid and the like. In the absence of any particular modification, the diffusion layer, 20, is formed over the entire surface of the silicon substrate, 10. The p-n junction is formed where the concentration of the p-type dopant equals the concentration of the n-type dopant; conventional cells that have the p-n junction close to the sun side, have a junction depth between 0.05 and 0.5 μm.

After formation of this diffusion layer excess surface glass is removed from the rest of the surfaces by etching by an acid such as hydrofluoric acid.

Next, an antireflective coating (ARC), 30, is formed on the n-type diffusion layer, 20, to a thickness of between 0.05 and 0.1 μm in the manner shown in FIG. 1D by a process, such as, for example, plasma chemical vapor deposition (CVD).

As shown in FIG. 1E, a front-side silver paste (front electrode-forming silver paste), 500, for the front electrode is screen printed and then dried over the antireflective coating, 30. In addition, a back-side silver or silver/aluminum paste, 70, and an aluminum paste, 60, are then screen printed (or some other application method) and successively dried on the back-side of the substrate. Normally, the back-side silver or silver/aluminum paste is screen printed onto the silicon first as two parallel strips (busbars) or as rectangles (tabs) ready for soldering interconnection strings (presoldered copper ribbons), the aluminum paste is then printed in the bare areas with a slight overlap over the back-side silver or silver/aluminum. In some cases, the silver or silver/aluminum paste is printed after the aluminum paste has been printed. Firing is then typically carried out in a belt furnace for a period of 1 to 5 minutes with the wafer reaching a peak temperature in the range of 600 to 900° C. The front and back electrodes can be fired sequentially or cofired.

Consequently, as shown in FIG. 1F, molten aluminum from the paste dissolves the silicon during the firing process and then on cooling forms a eutectic layer that epitaxially grows from the silicon base, 10, forming a p+ layer, 40, containing a high concentration of aluminum dopant. This layer is generally called the back surface field (BSF) layer, and helps to improve the energy conversion efficiency of the solar cell. A thin layer of aluminum is generally present at the surface of this epitaxial layer.

The aluminum paste is transformed by firing from a dried state, 60, to an aluminum back electrode, 61. The back-side silver or silver/aluminum paste, 70, is fired at the same time, becoming a silver or silver/aluminum back electrode, 71. During firing, the boundary between the back-side aluminum and the back-side silver or silver/aluminum assumes an alloy state, and is connected electrically as well. The aluminum electrode accounts for most areas of the back electrode, owing in part to the need to form a p+ layer, 40. Since soldering to an aluminum electrode is impossible, a silver or silver/aluminum back electrode is formed over portions of the back-side (often as 2 to 6 mm wide busbars) as an electrode for interconnecting solar cells by means of pre-soldered copper ribbon or the like. In addition, the front-side silver paste, 500, sinters and penetrates through the antireflective coating, 30, during firing, and is thereby able to electrically contact the n-type layer, 20. This type of process is generally called “firing through”. This fired through state is apparent in layer 501 of FIG. 1F.

A problem associated with silicon solar cells having an aluminum back electrode is bowing due to the mismatch of thermal expansion of silicon and aluminum layers. Bowing is undesirable in that it might lead to cracking and breaking the solar cells. Bowing also causes problems with regard to cell processing. During processing silicon cells are generally lifted up using automatic handling equipment which may not work reliably in case of excessive bowing. Overcoming the bowing problem is a challenge especially for silicon cell made from large and/or thin silicon wafers for example, silicon wafers having thickness of below 180 μm.

Another problem associated with the aluminum paste is dusting and transfer of free aluminum or alumina dust to other metallic surfaces, thereby reducing the solderability and adhesion of ribbons tabbed to said surface. This is particularly relevant when the firing process is performed with stacked solar cells.

US-A-2007/0079868 discloses aluminum thick film compositions which can be used in forming aluminum back electrodes of silicon solar cells. Apart from aluminum powder, an organic medium as vehicle and glass frit as an optional constituent, the aluminum thick film compositions comprise amorphous silicon dioxide as an essential constituent. The amorphous silicon dioxide serves in particular to reduce the bowing behavior of the silicon solar cells.

Similarly, US 2009/0255583A1 discloses aluminum thick film compositions which can be used in forming aluminum back electrodes of silicon solar cells. Apart from aluminum powder, an organic medium as vehicle and glass frit, silicon dioxide and zn-organic component as an optional constituents, the aluminum thick film compositions comprise tin-organic component as an essential constituent. The tin-organic component serves in particular to reduce the bowing behavior of the silicon solar cells.

It has now been found that aluminum thick film compositions having a similar or even better performance can be obtained when the aluminum thick film compositions disclosed in US-A-2007/0079868 or US 2009/0255583A1 comprise certain alkaline earth metal salts with organic counterions instead of or in addition to either the amorphous silicon dioxide or the Sn-organic component or both. The cell bowing problem described above can be minimized with the novel aluminum thick film compositions. Use of said novel aluminum thick film compositions in the production of aluminum back electrodes of silicon solar cells results in silicon solar cells exhibiting not only low bowing but also good adhesion of the fired aluminum back surface field to the back-side of the silicon wafer without compromising electrical performance such as cell efficiency.

These properties can be obtained in paste compositions with or without the presence of glass frit(s).

### SUMMARY OF THE INVENTION

The present invention relates to aluminum pastes (aluminum thick film compositions) for use in forming p-type aluminum back electrodes of silicon solar cells. It further relates to the process of forming and use of the aluminum pastes in the production of silicon solar cells and the silicon solar cells themselves.

The present invention is directed to aluminum pastes comprising: particulate aluminum, an organic vehicle, an additive comprising a salt of an alkaline earth metal ion and an organic counterion and, as optional components: amorphous silicon dioxide, Zn and/or Sn organometallic additives and one or more glass frit compositions.

The present invention is further directed to a process of forming a silicon solar cell and the silicon solar cell itself which utilizes a silicon wafer having a p-type and an n-type region, and a p-n junction, which comprises applying, in particular, screen-printing an aluminum paste of the present invention on the back-side of the silicon wafer, and firing the printed surface, whereby the wafer reaches a peak temperature in the range of 600 to 900° C.

### BRIEF DESCRIPTION OF THE FIGURES

FIG. 1 is a process flow diagram illustrating exemplary the fabrication of a silicon solar cell.

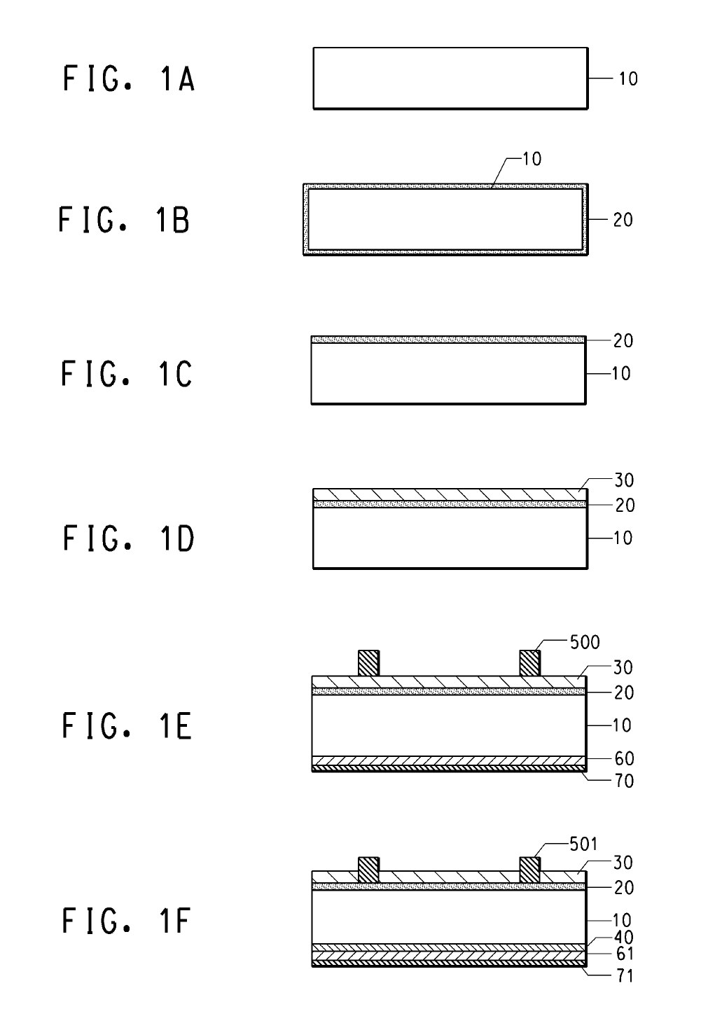

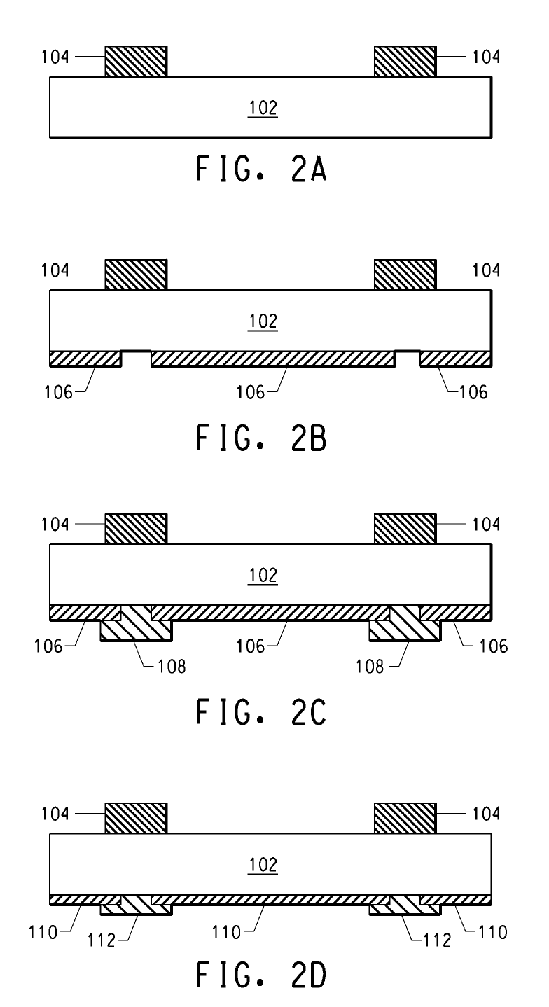

Reference numerals shown in FIG. 1 are explained below.
10: p-type silicon wafer
20: n-type diffusion layer
30: antireflective coating, for example, SiNx, TiOx, SiOx
40: p+ layer (back surface field, BSF)
60: aluminum paste formed on back-side
61: aluminum back electrode (obtained by firing back-side aluminum paste)
70: silver or silver/aluminum paste formed on back-side
71: silver or silver/aluminum back electrode (obtained by firing back-side silver or silver/aluminum paste)
500: silver paste formed on front-side
501: silver front electrode (obtained by firing front-side silver paste)

FIGS. 2A-D explain the manufacturing process for manufacturing a silicon solar cell using an electroconductive aluminum paste of the present invention. Reference numerals shown in FIG. 2 are explained below.
102 silicon substrate (silicon wafer)
104 light-receiving surface side electrode
106 paste composition for a first electrode
108 electroconductive paste for a second electrode
110 first electrode
112 second electrode

### DETAILED DESCRIPTION OF THE INVENTION

The aluminum pastes of the present invention comprise particulate aluminum, an alkaline earth metal salt with an organic counterion, an organic vehicle (organic medium) and, in optional embodiments, amorphous silicon dioxide, organometallic additives and one or more glass frit compositions alone or in combinations.

The particulate aluminum may be comprised of aluminum or an aluminum alloy with one or more other metals like, for example, zinc, tin, silver and magnesium. In case of aluminum powders the aluminum content is, for example, 99.5 to below 100 wt. %. The particulate aluminum may comprise aluminum particles in various shapes, for example, aluminum flakes, spherical-shaped aluminum powder, nodular-shaped (irregular-shaped) aluminum powder or any combinations thereof. Particulate aluminum, in an embodiment, is in the form of aluminum powder. The aluminum powder exhibits an average particle size (mean particle diameter) determined by means of laser scattering of, for example, 3 to 10 μm. The particulate aluminum may be present in the aluminum pastes of the present invention in a proportion of 50 to 80 wt. %, or, in an embodiment, 60 to 77 wt. %, based on total aluminum paste composition.

In the present description and the claims the term “total aluminum paste composition” is used. It shall mean aluminum paste composition as supplied to the user or customer.

All statements made in the present description and the claims in relation to average particle sizes relate to average particle sizes of the relevant materials as are present in the aluminum paste composition as supplied to the user or customer.

The particulate aluminum present in the aluminum pastes may be accompanied by other particulate metal(s) such as, for example, silver or silver alloy powders. The proportion of such other particulate metal(s) is, for example, 0 to 10 wt. %, based on the total of particulate aluminum plus particulate metal(s).

The aluminum pastes of the present invention comprise an additive comprising a salt of an alkaline earth metal ion and an organic counterion. In an embodiment, the additive comprising a salt of an alkaline earth metal ion and an organic counterion may be a liquid component. The term “an additive comprising a salt of an alkaline earth metal ion and an organic counterion” herein refers to solid compounds and liquid alkaline earth metal-organic components.

The term “an additive comprising a salt of an alkaline earth metal ion and an organic counterion” component of the aluminum pastes of the present invention, in a non-limiting embodiment, is substantially free of unoxidized alkaline earth metal; in a further embodiment, the alkaline earth metal-organic component may be greater than 90% free of unoxidized alkaline earth metal; in a further embodiment, the alkaline earth metal-organic component may be greater than 95%, 97%, or 99% free of unoxidized alkaline earth metal. In an embodiment, “an additive comprising a salt of an alkaline earth metal ion and an organic counterion” may be free of unoxidized alkaline earth metal.

In the context of the present invention the term “an additive comprising a salt of an alkaline earth metal ion and an organic counterion” includes such metal compounds that comprise at least one organic moiety in the molecule. “An additive comprising a salt of an alkaline earth metal ion and an organic counterion” is stable or essentially stable, for example, in the presence of atmospheric oxygen or air humidity, under the conditions prevailing during preparation, storage, and application of the aluminum pastes of the present invention. The same is true under the application conditions, in particular, under those conditions prevailing during screen printing of the aluminum pastes onto the back-side of the silicon wafers. However, during firing of the aluminum pastes the organic counterion portion of the “salt of an alkaline earth metal ion and an organic counterion” will or will essentially be removed, for example, burned and/or carbonized. The alkaline earth metal ion after firing is frequently present as an oxide and/or hydroxide.

Examples of suitable “salts of an alkaline earth metal ion and an organic counterion” include in particular alkaline earth metal carbonates, resinates (calcium salts of acidic resins, in particular, resins with carboxyl groups such as octanoates) and alkaline earth metal carboxylates (calcium carboxylic acid salts). It also includes mixed alkaline earth metal salts with organic counterions, for example, calcium magnesium carbonate. It also includes mixtures of salts, for example calcium carbonate and calcium oxalate.

The “salt of an alkaline earth metal ion and an organic counterion” may be present in the aluminum pastes of the present invention in a proportion corresponding to a salt contribution of 0.1 to 15 wt. %, or, in an embodiment, 0.1 to 3.0 wt. %, based on the total solid content of the Al paste composition.

In the case of alkaline earth metal carbonate, its proportion in the aluminum pastes may be in the range of 0.1 to 7.0 wt. %, or, in an embodiment, 0.1 to 3.0 wt. %, based on total solid content of the aluminum paste composition. At concentrations above the cited values, cell bowing is further reduced but the electrical performance may deteriorate.

In an embodiment, the aluminum pastes of the present invention may comprise at least one glass frit composition as an inorganic binder. The glass frit compositions may contain PbO; in an embodiment, the glass frit compositions may be lead free. The glass frit compositions may comprise those which upon firing undergo recrystallization or phase separation and liberate a frit with a separated phase that has a lower softening point than the original softening point.

The (original) softening point (glass transition temperature, determined by differential thermal analysis DTA at a heating rate of 10 K/min) of the glass frit compositions may be in the range of 325 to 600° C.

The glass frits exhibit average particle sizes (mean particle diameters) determined by means of laser scattering of, for example, 2 to 20 μm. In case of the aluminum pastes comprising glass-frit(s) the glass frit(s) content may be 0.01 to 5 wt. %, or, in an embodiment, 0.1 to 2 wt. %, or, in a further embodiment, 0.2 to 1.25 wt. %, based on total aluminum paste composition.

Some of the glass frits useful in the aluminum pastes are conventional in the art. Some examples include borosilicate and aluminosilicate glasses. Examples further include combinations of oxides, such as: B₂O₃, SiO₂, Al₂O₃, CdO, CaO, BaO, ZnO, Na₂O, Li₂O, PbO, and ZrO₂ which may be used independently or in combination to form glass binders.

The conventional glass frits may be the borosilicate frits, such as lead borosilicate frit, bismuth, cadmium, barium, calcium, or other alkaline earth borosilicate frits. The preparation of such glass frits is well known and consists, for example, in melting together the constituents of the glass in the form of the oxides of the constituents and pouring such molten composition into water to form the frit. The batch ingredients may, of course, be any compounds that will yield the desired oxides under the usual conditions of frit production. For example, boric oxide will be obtained from boric acid, silicon dioxide will be produced from flint, barium oxide will be produced from barium carbonate, etc.

The glass may be milled in a ball mill with water or inert low viscosity, low boiling point organic liquid to reduce the particle size of the frit and to obtain a frit of substantially uniform size. It may then be settled in water or said organic liquid to separate fines and the supernatant fluid containing the fines may be removed. Other methods of classification may be used as well.

The glasses are prepared by conventional glassmaking techniques, by mixing the desired components in the desired proportions and heating the mixture to form a melt. As is well known in the art, heating may be conducted to a peak temperature and for a time such that the melt becomes entirely liquid and homogeneous.

The aluminum pastes of the present invention may comprise amorphous silicon dioxide. The amorphous silicon dioxide is a finely divided powder. In an embodiment, it may have an average particle size (mean particle diameter) determined by means of laser scattering of, for example, 5 to 100 nm. Particularly it comprises synthetically produced silica, for example, pyrogenic silica or silica produced by precipitation. Such silicas are supplied by various producers in a wide variety of types.

In case the aluminum pastes of the present invention comprise amorphous silicon dioxide, the latter may be present in the aluminum pastes in a proportion of, for example, above 0 to 0.5 wt. %, for example, 0.01 to 0.5 wt. %, or, in an embodiment, 0.05 to 0.1 wt. %, based on total aluminum paste composition.

The aluminum pastes of the present invention may comprise Zn and/or Sn organic component. In case the aluminum pastes of the present invention comprise Zn and/or Sn organic components may be present in the aluminum pastes in a proportion of, for example, above 0 to 3.0 wt. %, for example, 0.01 to 3.0 wt. %, or, in an embodiment, 0.05 to 1.0 wt. %, based on total aluminum paste composition.

The aluminum pastes of the present invention comprise an organic vehicle at a concentration of 9.9-49.9% by weight of the total paste composition. A wide variety of inert materials can be used as organic vehicle. The organic vehicle may be one in which the particulate constituents (particulate aluminum, amorphous silicon dioxide if any, glass frit if any) are dispersible with an adequate degree of stability. The properties, in particular, the rheological properties, of the organic vehicle may be such that they lend good application properties to the aluminum paste composition, including: stable dispersion of insoluble solids, appropriate viscosity and thixotropy for application, in particular, for screen printing, appropriate wettability of the silicon wafer substrate and the paste solids, a good drying rate, and good firing properties. The organic vehicle used in the aluminum pastes of the present invention may be a nonaqueous inert liquid. The organic vehicle may be an organic solvent or an organic solvent mixture; in an embodiment, the organic vehicle may be a solution of organic polymer(s) in organic solvent(s). In an embodiment, the polymer used for this purpose may be ethyl cellulose. Other examples of polymers which may be used alone or in combination include ethylhydroxyethyl cellulose, wood rosin, phenolic resins and poly(meth)acrylates of lower alcohols. Examples of suitable organic solvents comprise ester alcohols and terpenes such as alpha- or beta-terpineol or mixtures thereof with other solvents such as kerosene, dibutylphthalate, diethylene glycol butyl ether, diethylene glycol butyl ether acetate, hexylene glycol and high boiling alcohols. In addition, volatile organic solvents for promoting rapid hardening after application of the aluminum paste on the back-side of the silicon wafer can be included in the organic vehicle. Various combinations of these and other solvents may be formulated to obtain the viscosity and volatility requirements desired.

The aluminum pastes of the present invention may comprise one or more organic additives, for example, surfactants, thickeners, rheology modifiers and stabilizers. The organic additive(s) may be part of the organic vehicle. However, it is also possible to add the organic additive(s) separately when preparing the aluminum pastes. The organic additive(s) may be present in the aluminum pastes of the present invention in a total proportion of, for example, 0 to 10 wt. %, based on total aluminum paste composition.

The organic vehicle content in the aluminum pastes of the present invention may be dependent on the method of applying the paste and the kind of organic vehicle used, and it can vary. In an embodiment, it may be from 9.9 to 49.9 wt. %, or, in an embodiment, it may be in the range of 22 to 35 wt. %, based on total aluminum paste composition. The number of 9.9 to 49.9 wt. % includes organic solvent(s), possible organic polymer(s) and possible organic additive(s).

The aluminum pastes of the present invention are viscous compositions, which may be prepared by mechanically mixing the particulate aluminum, the alkaline earth metal-organic component, the optional glass frit composition(s) and the optional amorphous silicon dioxide with the organic vehicle. In an embodiment, the manufacturing method power mixing, a dispersion technique that is equivalent to the traditional roll milling, may be used; roll milling or other mixing technique can also be used.

The aluminum pastes of the present invention may be used in the manufacture of aluminum back electrodes of silicon solar cells or respectively in the manufacture of silicon solar cells. The manufacture may be performed by applying the aluminum pastes to the back-side of silicon wafers, i.e., to those surface portions thereof which are or will not be covered by other back-side metal pastes like, in particular, back-side silver or silver/aluminum pastes. The silicon wafers may comprise monocrystalline or polycrystalline silicon. In an embodiment, the silicon wafers may have an area of 100 to 250 cm² and a thickness of 180 to 300 μm. However, the aluminum pastes of the present invention can be successfully used even for the production of aluminum back electrodes on the back-side of silicon wafers that are larger and/or having a lower thickness, for example, silicon wafers having a thickness below 180 μm, in particular in the range of 120 to below 180 μm and/or an area in the range of above 250 to 400 cm².

The aluminum pastes are applied to a dry film thickness of, for example, 15 to 60 μm. The method of aluminum paste application may be printing, for example, silicone pad printing or, in an embodiment, screen printing. The application viscosity of the aluminum pastes of the present invention may be 20 to 200 Pa·s when it is measured at a spindle speed of 10 rpm and 25° C. by a utility cup using a Brookfield HADV-1 Prime viscometer (Brookfield Inc., Middleboro, Mass.) and #14 spindle.

After application of the aluminum pastes to the back-side of the silicon wafers they may be dried, for example, for a period of 1 to 100 minutes with the wafers reaching a peak temperature in the range of 100 to 300° C. Drying can be carried out making use of, for example, belt, rotary or stationary driers, in particular, IR (infrared) belt driers.

After their application or, in an embodiment, after their application and drying, the aluminum pastes of the present invention are fired to form aluminum back electrodes. Firing may be performed, for example, for a period of 1 to 5 minutes with the silicon wafers reaching a peak temperature in the range of 600 to 900° C. Firing can be carried out making use of, for example, single or multi-zone belt furnaces, in particular, multi-zone IR belt furnaces. Firing happens in the presence of oxygen, in particular, in the presence of air. During firing the organic substance including non-volatile organic material and the organic portion not evaporated during the possible drying step may be removed, i.e. burned and/or carbonized, in particular, burned. The organic substance removed during firing includes organic solvent(s), possible organic polymer(s), possible organic additive(s) and the organic moieties of the one or more alkaline earth metal-organic compounds. The alkaline earth may remain as alkaline earth oxide and/or hydroxide after firing. In case the aluminum pastes comprise glass frit(s), there may be a further process taking place during firing, namely sintering of the glass frit(s). Firing may be performed as so-called cofiring together with further metal pastes that have been applied to the silicon wafer, i.e., front-side and/or back-side metal pastes which have been applied to form front-side and/or back-side electrodes on the wafer's surfaces during the firing process. An embodiment includes front-side silver pastes and back-side silver or back-side silver/aluminum pastes.

Next, a non-limiting example in which a silicon solar cell is prepared using an aluminum paste of the present invention is explained, referring to FIG. 2.

First, a silicon wafer substrate 102 is prepared. On the light-receiving side face (front-side surface) of the silicon wafer, normally with the p-n junction close to the surface, front-side electrodes (for example, electrodes mainly composed of silver) 104 are installed (FIG. 2A). On the back-side of the silicon wafer, a silver or silver/aluminum electroconductive paste (for example, PV202 or PV502 or PV583 or PV581), commercially available from E.I. Du Pont de Nemours and Company, Wilmington, Del.) is spread to form either busbars or tabs to enable interconnection with other solar cells set in parallel electrical configuration. On the back-side of the silicon wafer, a novel aluminum paste of the present invention used as a back-side (or p-type contact) electrode for a solar cell, 106 is spread by screen printing using the pattern that enable slight overlap with the silver or silver/aluminum paste referred to above, etc., then dried (FIG. 2B). Drying of the pastes is performed, for example, in an IR belt drier for a period of 1 to 10 minutes with the wafer reaching a peak temperature of 100 to 300° C. Also, the aluminum paste may have a dried film thickness of 15 to 60 μm, and the thickness of the silver or silver/aluminum paste may be 15 to 30 μm. Also, the overlapped part of the aluminum paste and the silver or silver/aluminum paste may be about 0.5 to 2.5 mm.

Next, the substrate obtained is fired, for example, in a belt furnace for a period of 1 to 5 minutes with the wafer reaching a peak temperature of 600 to 900° C., so that the desired silicon solar cell is obtained (FIG. 2D). An electrode 110 is formed from the aluminum paste wherein said paste has been fired to remove the organic substance and, in case the aluminum paste comprises glass frit, to sinter the latter.

The silicon solar cell obtained using the aluminum paste of the present invention, as shown in FIG. 2D, has electrodes 104 on the light-receiving face (surface) of the silicon substrate 102, aluminum electrodes 110 mainly composed of aluminum and silver or silver/aluminum electrodes 112 mainly composed of silver or silver and aluminum (formed by firing silver or silver/aluminum paste 108), on the back-side.

### EXAMPLES

The examples cited here relate to thick-film metallization pastes used in forming back side contact in conventional solar cells.

The present invention can be applied to a broad range of semiconductor devices, although it is especially effective in light-receiving elements such as photodiodes and solar cells. The discussion below describes how a solar cell is formed utilizing the composition(s) of the present invention and how it is tested for its technological properties such as cell bowing, cell efficiency and paste adhesion.

### (i) Formation of Metallized Cell for Bowing Determination

On the back face of Si substrates (nominally 160 μm or 200 μm thick, multicrystalline silicon wafers of 0.5″×2.5″ area, boron doped p-type bulk silicon, with an n-type diffused POCl₃ emitter, surface texturized with acid, SiNₓ anti-reflective coating (ARC) on the wafer's emitter applied by CVD), an aluminum paste was screen-printed. For the purpose of the cell bowing study, there was no front side paste printed in this example. The rectangular geometry of the wafer is preferred because it leads to more pronounced bowing which makes evaluation of pastes more accurate.

The example aluminum paste A comprised 74 wt. % air-atomized aluminium powder (average particle size 6 μm), 26 wt. % organic vehicle of polymeric resins and organic solvents. In addition, the example aluminum paste A (according to the invention) comprised calcium salt additives in the range of 1 to 9 wt. %, by replacing Al content in the paste whereas the control example aluminum paste (comparative example) comprised no addition of calcium compounds. For the paste containing calcium salts, the calcium salt concentration given in the tables therefore is based on total solid content of the aluminum paste composition.

The example aluminum paste B comprised 72 wt. % air-atomized aluminium powder (average particle size 6 μm), 26 wt. % organic vehicle of polymeric resins and organic solvents, 0.07 wt. % amorphous silica, 1% zinc neodecanoate, 0.5% tin octanoate and 0.2% frit. In addition, the example aluminum paste B (according to the invention) comprised calcium salt additives in the range of 1 to 9 wt. % by replacing Al content in the paste, whereas the control example aluminum paste (comparative example) comprised no addition of calcium compounds.

The example aluminum paste C comprised 74 wt. % nitrogen-atomized aluminium powder (average particle size 6 μm), 26 wt. % organic vehicle of polymeric resins and organic solvents. In addition, the example aluminum paste C (according to the invention) comprised calcium salt additives in the range of 1 to 9 wt. %, by replacing Al content in the paste whereas the control example aluminum paste (comparative example) comprised no addition of calcium compounds.

The example aluminum paste D comprised 72 wt. % nitrogen-atomized aluminium powder (average particle size 6 μm), 26 wt. % organic vehicle of polymeric resins and organic solvents, 0.07 wt. % amorphous silica, 1% zinc neodecanoate, 0.5% tin octanoate and 0.2% frit. In addition, the example aluminum paste D (according to the invention) comprised calcium salt additives in the range of 1 to 9 wt. % by replacing Al content in the paste, whereas the control example aluminum paste (comparative example) comprised no addition of calcium compounds.

The example aluminum pastes E and F are commercial Al pastes, namely PV381 (E I DuPont Nemours Company, Wilmington, Del.) and Ruxing RX8204 (Ruxing, Guangzhou City, Guangdong Province. China) comprising (according to the information disclosed in the MSDS sheet) 70-75 wt % Al, 10-15 wt % 2-(2-Butoxyethoxy) ethanol, 10-15 wt % Pine oil in paste E, and 60-65 wt % Al, 1-5 wt % 2-(2-Butoxyethoxy) ethanol, 15-20 wt % Terpineol, 1-5 wt % Methyl Carbitol in paste F respectively. In addition, the example aluminum pastes E and F (according to the invention) comprised calcium salt additions in the range of 1 to 9 wt. % by replacing Al content in the paste, whereas the control example aluminum paste (comparative example) comprised no addition of calcium compounds.

The example aluminum paste G comprised 72 wt. % air-atomized aluminium powder (average particle size 6 μm), 26 wt. % organic vehicle of polymeric resins and organic solvents, 0.07 wt. % amorphous silica, 1 wt. % zinc neodecanoate, and 0.5% tin octanoate. In addition, the example aluminum paste G (according to the invention) comprised calcium salt additives of 3 wt. % by replacing Al content in the paste, whereas the control example aluminum paste (comparative example) comprised no addition of calcium compounds.

The printed wafers were first dried at 150° C. for 20 mins and then fired in a 6-zone IR furnace PV614 reflow oven (Radiant Technology Corp., Fullerton, Calif.) at a belt speed of 180 in/min with zone temperatures defined as zone 1=550° C., zone 2=600° C., zone 3=650° C., zone 4=700° C., zone 5=800° C., and the final zone 6 set at 840-940° C., thus the wafers reaching a peak temperature of 740-840° C. The zone 6 set point temperature is the cell firing temperature referred in Tables 1 and 2.

A special jig was made to facilitate easy and accurate cell bowing measurement of samples printed with above pastes. This consisted of table about 1 by 1 foot wide with legs of about 6 inches high. The table top was very flat, and had a half inch hole in the middle. The hole was tapered so that the hole size on the bottom of the table top was larger than the hole size on the top to facilitate the measurement. The measurement head of a Keyence LC-2001 (Missisauga, Ontario, CANADA) Laser Displacement Meter was mounted to the underside of the table top with the laser beam projecting straight upward through the hole in the table top. The sample was placed on the flat table top such that its center was centered over the hole. The LC-2001 read out the height of location where the beam intersected the bowed sample in microns. The accuracy was about +/−1 micron. The zero is verified by placing a known flat sample on the table top. The calibration was verified by moving the LC-2001 up and down using a micrometer. Table 1 comprise the bow results of pastes A to F printed on 160 μm wafer. Table 2 comprise the bow results of pastes A and B printed on 200 μm wafer

TABLE 1
Wafer bowing results using pastes A to F on 160 μm wafer thickness

| | | | | | Additive | | |
|---|---|---|---|---|---|---|---|
| | | | | | wt % | Cell | |
| | Wafer | Wafer | No of | | based on | Firing | Median |
| | Thickness | dimensions | samples, | | total solid | Temp | Bow |
| Paste | (μm) | (L × W) | N | Additive | content | (° C.) | (mm) |
| A | 160 | 0.5″ × 2.5″ | 5 | None | 0 | 875 | 0.432 |
| A | 160 | 0.5″ × 2.5″ | 3 | Calcium | 3 | 875 | 0.273 |
| | | | | Carbonate | | | |
| A | 160 | 0.5″ × 2.5″ | 5 | Calcium | 1 | 875 | 0.341 |
| | | | | Oxalate | | | |
| A | 160 | 0.5″ × 2.5″ | 5 | Calcium | 3 | 875 | 0.275 |
| | | | | Oxalate | | | |
| A | 160 | 0.5″ × 2.5″ | 5 | Calcium | 9 | 875 | 0.222 |
| | | | | Oxalate | | | |
| A | 160 | 0.5″ × 2.5″ | 5 | Calcium | 1 | 875 | 0.299 |
| | | | | Magnesium | | | |
| | | | | Carbonate | | | |
| A | 160 | 0.5″ × 2.5″ | 5 | Calcium | 3 | 875 | 0.222 |
| | | | | Magnesium | | | |
| | | | | Carbonate | | | |
| A | 160 | 0.5″ × 2.5″ | 5 | Calcium | 9 | 875 | 0.163 |
| | | | | Magnesium | | | |
| | | | | Carbonate | | | |
| A | 160 | 0.5″ × 2.5″ | 5 | Calcium | 5 | 875 | 0.333 |
| | | | | Octanoate | | | |
| | | | | (5% Ca) | | | |
| A | 160 | 0.5″ × 2.5″ | 5 | Calcium | 15 | 875 | 0.241 |
| | | | | Octanoate | | | |
| | | | | (5% Ca) | | | |
| B | 160 | 0.5″ × 2.5″ | 3 | None | 0 | 875 | 0.308 |
| B | 160 | 0.5″ × 2.5″ | 3 | Calcium | 3 | 875 | 0.204 |
| | | | | Carbonate | | | |
| C | 160 | 0.5″ × 2.5″ | 5 | None | 0 | 900 | 0.463 |
| C | 160 | 0.5″ × 2.5″ | 5 | Calcium | 3 | 900 | 0.310 |
| | | | | Carbonate | | | |
| C | 160 | 0.5″ × 2.5″ | 5 | Calcium | 9 | 900 | 0.228 |
| | | | | Carbonate | | | |
| D | 160 | 0.5″ × 2.5″ | 5 | None | 0 | 900 | 0.176 |
| D | 160 | 0.5″ × 2.5″ | 5 | Calcium | 3 | 900 | 0.135 |
| | | | | Carbonate | | | |
| D | 160 | 0.5″ × 2.5″ | 5 | Calcium | 9 | 900 | 0.127 |
| | | | | Carbonate | | | |
| E | 160 | 0.5″ × 2.5″ | 3 | Calcium | 0 | 860 | 0.461 |
| | | | | Carbonate | | | |
| E | 160 | 0.5″ × 2.5″ | 3 | Calcium | 3 | 860 | 0.419 |
| | | | | Carbonate | | | |
| E | 160 | 0.5″ × 2.5″ | 3 | Calcium | 9 | 860 | 0.325 |
| | | | | Carbonate | | | |
| F | 160 | 0.5″ × 2.5″ | 3 | Calcium | 0 | 860 | 0.420 |
| | | | | Carbonate | | | |
| F | 160 | 0.5″ × 2.5″ | 3 | Calcium | 3 | 860 | 0.264 |
| | | | | Carbonate | | | |
| F | 160 | 0.5″ × 2.5″ | 3 | Calcium | 9 | 860 | 0.212 |
| | | | | Carbonate | | | |

TABLE 2
Wafer bowing results using pastes A to F on 200 μm wafer thickness.

| | | | | | Additive | | |
|---|---|---|---|---|---|---|---|
| | | | | | wt % | Cell | |
| | Wafer | Wafer | No of | | based on | Firing | Median |
| | Thickness | dimensions | samples, | | total solid | Temp | Bow |
| Paste | (um) | (L × W) | N | Additive | content | (° C.) | (mm) |
| A | 200 | 0.5″ × 2.5″ | 3 | Calcium | 0 | 875 | 0.235 |
| | | | | Carbonate | | | |
| A | 200 | 0.5″ × 2.5″ | 3 | Calcium | 3 | 875 | 0.146 |
| | | | | Carbonate | | | |
| B | 200 | 0.5″ × 2.5″ | 3 | Calcium | 0 | 875 | 0.149 |
| | | | | Carbonate | | | |
| B | 200 | 0.5″ × 2.5″ | 3 | Calcium | 3 | 875 | 0.124 |
| | | | | Carbonate | | | |

### (ii) Formation of Solar Cells for Bowing and Electrical Performance Determinations

On the back face of a Si substrate (160 μm thick multicrystalline silicon wafer of 6″×6″ area, boron doped p-type bulk silicon, with an n-type diffused POCl₃ emitter, surface texturized with acid, SiNₓ anti-reflective coating (ARC) on the wafer's emitter applied by CVD) having a 20 μm thick silver electrode on the front surface (PV145 Ag composition commercially available from E. I. Du Pont de Nemours and Company) an Ag/Al paste (PV202, an Ag/Al composition commercially available from E. I. Du Pont de Nemours and Company, Wilmington, Del.) was printed and dried as 5 mm wide bus bars. Then, an aluminum paste for the back face electrode of a solar cell was screen-printed at a dried film thickness of 30 μm providing overlap of the aluminum film with the Ag/Al busbar for 1 mm at both edges to ensure electrical continuity.

The printed wafers were first dried at 150° C. for 20 mins and then fired in a 6-zone IR furnace PV614 reflow oven (Radiant Technology Corp., Fullerton, Calif.) at a belt speed of 180 in/min with zone temperatures defined as zone 1=550° C., zone 2=600° C., zone 3=650° C., zone 4=700° C., zone 5=800° C., and the final zone 6 set at 840-940° C., thus the wafers reaching a peak temperature of 740-840° C. The zone 6 set point temperature is the cell firing temperature referred in Table 3. After firing, the metallized wafer became a functional photovoltaic device.

A commercial JV or Current—Voltage tester was used to make efficiency measurements of the multi-crystalline silicon photovoltaic cells. The tester model was a ST-1000 made by Telecom-STV Ltd. (Moscow, Russia). The samples were typically 28 mm by 28 mm but the instrument can handle wafers up to 6 inches by 6 inches. Two electrical connections, one for voltage and one for current, are made both on the top and bottom of the photovoltaic samples. A flash lamp at more than a meter from the sample is used to simulate the solar spectrum and intensity. The lamp power is held constant for about 14 milliseconds. The intensity at the sample surface is 1000 W/m² (or 1 Sun) during this time period. During the 14 milliseconds the tester varies an artificial electrical load on the sample. The load varies short circuit to open circuit. (A real load would be limited to this range, but the artificial load is in fact extended slightly beyond open circuit and short circuit conditions during this test.) The tester records the light induced current through, and the voltage across the photovoltaic sample while the load changes over the stated range of loads. A power versus voltage curve is obtained from this data by taking the product of the current times the voltage at each voltage level. The maximum of the power versus voltage curve is the “maximum power” which is used to calculate the efficiency. The maximum power is divided by the area of the sample to obtain the maximum power per area out at 1 Sun intensity. This is then divided by 1000 W/m² of the input intensity to obtain the efficiency which is then multiplied by 100 to present the result in percent efficiency. Other parameters of interest are also obtained from this same current-voltage curve. Of special interest are the open circuit voltage, the voltage where the current is zero, the short circuit current which is the current when the voltage is zero, and estimates of the series and shunt resistances that are obtained from the reciprocal of the local slope of the current voltage curve near the short circuit and open circuit points respectively.

The cell bowing was recorded after firing by measuring the distance between the maximum curvature of the wafer to the base plane with a ruler. The cell bowing along with cell efficiency results are summarized in Table 3.

TABLE 3
Cell efficiency and cell bowing results of pastes A and B using 6″ × 6″ cell.

| | | | | | Additive | | | |
|---|---|---|---|---|---|---|---|---|
| | | | | | wt % | Cell | | |
| | Wafer | Wafer | No of | | based on | Firing | | Cell |
| | Thickness | dimensions | samples, | | total solid | Temp, | Bow | Eff |
| Paste | (um) | (L × W) | N | Additive | content | (° C.) | (mm) | (%) |
| A | 160 | 6″ × 6″ | 1 | Calcium Carbonate | 0 | 870 | 4.32 | 16.42 |
| A | 160 | 6″ × 6″ | 1 | Calcium Carbonate | 3 | 870 | 3.20 | 16.54 |
| B | 160 | 6″ × 6″ | 1 | Calcium Carbonate | 0 | 870 | 1.91 | 16.44 |
| B | 160 | 6″ × 6″ | 1 | Calcium Carbonate | 3 | 870 | 0.25 | 16.50 |

(iii) Adhesion Test

In order to measure the cohesive strength of the Al metallizations the amount of material removed from the surface of the fired wafer prepared as in ii) above, was determined using a peel test. To this end a transparent layer of adhesive tape was applied to tared samples of 1.05″×1.05″ cells. The tape was applied using a tared aluminum foil template to define the area of contact with the wafer (0.78 cm²). The tape was subsequently peeled off and both the wafer and the tape were re-weighed using an analytical balance (Mettler MTS, Columbus, Ohio). The weight differences of both wafer and the tape are shown in Table 4 as mean values of four separate measurements.

TABLE 4
Adhesion test results based on weight measurements.

| | | Firing | Wafer | | Mean Wt | Mean Wt |
|---|---|---|---|---|---|---|
| | | Temp, | Thick | | loss in | gain in |
| Sample ID | Sample Description | (C.) | (um) | Adhesion | Wafer, μg | Tape, μg |
| 180-5 | Paste B | 900 | 200 | Moderate | −89 | +99 |
| 288-20 | Paste B + 3% CaCO₃ | 875 | 200 | Improved | −8 | +78 |
| 292-6 | Paste G | 900 | 200 | Poor | −856 | +920 |
| 292-14 | Paste G + 3% CaCO₃ | 900 | 200 | Improved | −343 | +346 |

What is claimed is:

1. A composition comprising:
a) 50 to 80% by weight of the total composition of an aluminum powder
b) 9.9 to 49.9% by weight of the total composition of an organic vehicle
c) 0.1 to 15% by weight of the total solid content of paste composition of an additive comprising a salt of an alkaline earth metal ion and an organic counterion wherein the organic counterion is selected from the group consisting of carboxylates, phenylates and resonates.

2. A composition comprising:
a) 50 to 80% by weight of the total composition of an aluminum powder
b) 9.9 to 49.9% by weight of the total composition of an organic vehicle
c) 0.1 to 7.0% by weight of the total solid content of paste composition of an additive comprising a salt of an alkaline earth metal ion and an organic counterion wherein the organic counterion is carbonate.

3. A process of forming a silicon solar cell comprising the steps:
(i) applying the composition of claim 1 on the back-side of a silicon wafer having a p-type region, an n-type region and a p-n junction, and
(ii) firing the surface provided with the composition, whereby the wafer reaches a peak temperature of 600 to 900° C. wherein the organic counterion is essentially removed.

4. A process of forming a silicon solar cell comprising the steps:
(i) applying the composition of claim 2 on the back-side of a silicon wafer having a p-type region, an n-type region and a p-n junction, and
(ii) firing the surface provided with the composition, whereby the wafer reaches a peak temperature of 600 to 900° C. wherein the organic counterion is essentially removed.

5. The process of claim 3 or claim 4, wherein the application of the composition is performed by screen printing.

6. The process of claim 3 or claim 4, wherein firing is performed as cofiring together with other front-side and/or back-side metal pastes that have been applied to the silicon wafer to form front-side and/or back-side electrodes thereon during firing.

7. Silicon solar cells made by the process of claim 3.

8. Silicon solar cells made by the process of claim 4.

9. A silicon solar cell comprising an aluminum back electrode wherein the aluminum back electrode is produced making use of a composition of claim 1.

10. A silicon solar cell comprising an aluminum back electrode wherein the aluminum back electrode is produced making use of a composition of claim 2.

11. The silicon solar cell of claim 9 or claim 10, further comprising a silicon wafer.
